(19) United States
(12) Patent Application Publication
(10) Pub. No.: US 2006/0023438 A1
(43) Pub. Date: Feb. 2, 2006

(54) Wiring board and method of manufacturing wiring board

(76) Inventor: Akihiko Happoya, Fussa-shi (JP)

Correspondence Address: PILLSBURY WINTHROP SHAW PITTMAN, LLP, P.O. BOX 10500, MCLEAN, VA, 22102, US

(21) Appl. No.: 11/138,390

(22) Filed: May 27, 2005

(30) Foreign Application Priority Data
Jul. 28, 2004 (JP) P2004-219978

(51) Int. Cl. H05K 7/06

(52) U.S. Cl. 361/761; 361/767

(57) ABSTRACT

A sub wiring board 6 is fixed to a main wiring board so that an electronic component 10 mounted on the sub wiring board 6 is housed inside a recessed portion 5 of the main wiring board. Over the sub wiring board 6, a large electronic component 20 is arranged to cover the sub wiring board 6 and is fixed to the main wiring board.

### CROSS-REFERENCE TO THE INVENTION

This application is based upon and claims the benefit of priority from the prior Japanese Patent Application No. 2004-219978, filed on Jul. 30, 2004; the entire contents of which are incorporated herein by reference.

### BACKGROUND OF THE INVENTION

1. Field of the Invention

The present invention relates to a wiring board and a method of manufacturing the wiring board and, more particularly, to the wiring board and the method of manufacturing the wiring board suitable for a portable device, small electronic device and the like.

2. Description of the Related Art

As the portable device and electronic device are made more sophisticated and reduced in size and weight, miniaturization and densification of the wiring board are also in progress, and a multilayer wiring board in which conductor patterns are formed in multilayer is often used.

It is also known that the size of the wiring board like this is reduced by providing a counterbore portion in a part of the wiring board in such a manner to form a recessed portion, and mounting an electronic device on a cover provided at the counterbore portion (refer to Japanese Patent Laid-open Application No. Hei 10-290054, for example).

However, the sophistication and reduction in size and weight of the portable device and the electronic device are made further more, and further miniaturization and densification of the wiring board are desired as well.

### SUMMARY OF THE INVENTION

The present invention is made in view of such conventional circumstances, and its object is to provide a wiring board and a method of manufacturing the wiring board by which miniaturization and densification are made possible as compared to the conventional art.

A wiring board according to an embodiment of the present invention comprises a main wiring board constituted of a multilayer wiring board, and having a recessed portion in a predetermined shape formed therein, a sub wiring board having a first electronic component mounted thereon, and fixed to the main wiring board so that the first electronic component is positioned inside the recessed portion, and a second electronic component whose size is larger than the sub wiring board, arranged to cover an upper part of the sub wiring board, and fixed electrically to the main wiring board.

A wiring board according to another embodiment of the present invention comprises a main wiring board constituted of a multilayer wiring board, and having a recessed portion in a predetermined shape formed therein, a sub wiring board having a first electronic component mounted thereon, and fixed to the main wiring board so that the first electronic component is positioned inside the recessed portion, and a second electronic component fixed to extend across the sub wiring board and the main wiring board.

A method of manufacturing a wiring board according to an embodiment of the present invention comprises manufacturing a sub wiring board comprising depositing cream solder on predetermined positions on a wiring board material on which a plurality of predetermined conductor patterns are formed, mounting a plurality of first electronic components on the predetermined positions on the wiring board material, thermally melting the cream solder to connect the first electronic components and the wiring board material, and cutting the wiring board material into separate subwiring boards, and connecting the sub wiring board and a main wiring board comprising forming a recessed portion in a predetermined shape in the main wiring board constituted of a multilayer wiring board, mounting the sub wiring board on the main wiring board so that the first electronic component is positioned inside the recessed portion, depositing the cream solder on a predetermined position, and thermally melting the cream solder to connect the sub wiring board and the main wiring board.

### BRIEF DESCRIPTION OF THE DRAWINGS

FIG. 1 is a view showing an enlarged schematic configuration of a main part of a wiring board according to an embodiment of the present invention.

FIGS. 2A to 2F are views showing manufacturing process of a sub wiring board.

FIGS. 3A to 3D are views showing connecting process of the sub wiring board and a main wiring board.

FIGS. 4A and 4B are views showing the state how electronic components are mounted on the wiring board.

FIGS. 5A to 5E are views showing manufacturing process of the wiring board shown in FIG. 4B.

FIG. 6 is a view showing the state how electronic components are mounted on a wiring board according to another embodiment of the present invention.

FIGS. 7A to 7E are views showing manufacturing process of the wiring board shown in FIG. 6.

FIG. 8 is a view showing the state how electronic components are mounted on a wiring board according to another embodiment of the present invention.

### DESCRIPTION OF THE EMBODIMENTS

Hereinafter, embodiments of the present invention will be explained in detail with reference to the drawings.

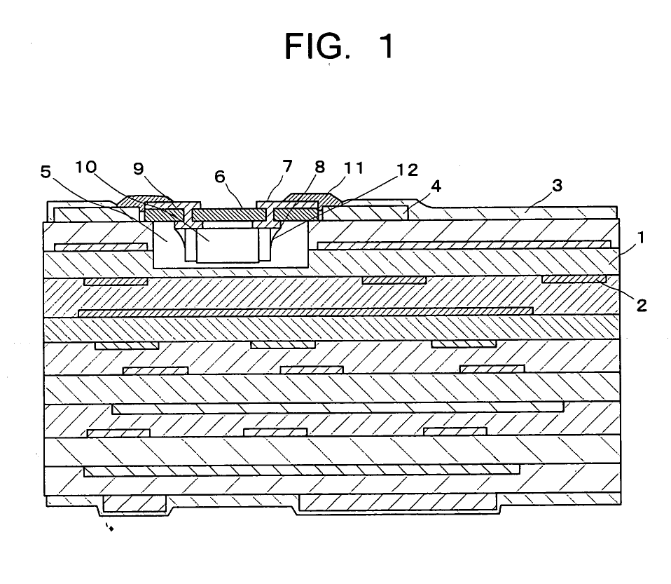

FIG. 1 shows an enlarged schematic configuration of a main part of a wiring board according to an embodiment of the present invention. As shown in the drawing, the wiring board has a main wiring board in which insulating layers 1 and conductor layers 2 are formed in multilayer, and a recessed portion 5 having a predetermined shape is formed in the main wiring board. At the recessed portion 5, a sub wiring board 6 on which an electronic component 10 is mounted is arranged so that the electronic component 10 is positioned inside the recessed portion 5, and a conductor pattern 7 of the sub wiring board 6 and a conductor pattern 4 of the main wiring board are connected and fixed by solder 11. The sub wiring board 6 and the main wiring board are connected not only by the solder, but also by conductive paste, anisotropic conductive materials such as ACF, ACP and the like. The entire size of the sub wiring board 6 is larger than the recessed portion 5, to thereby prevent the sub wiring board 6 from falling off into the recessed portion 5.

Incidentally, in FIG. 1, 3 denotes a solder resist covering the surface of the main wiring board, 9 denotes a via of the sub wiring board 6, 8 denotes a conductor pattern provided continuously to the via, and 12 denotes solder connecting the conductor pattern 8 and the electronic component 10.

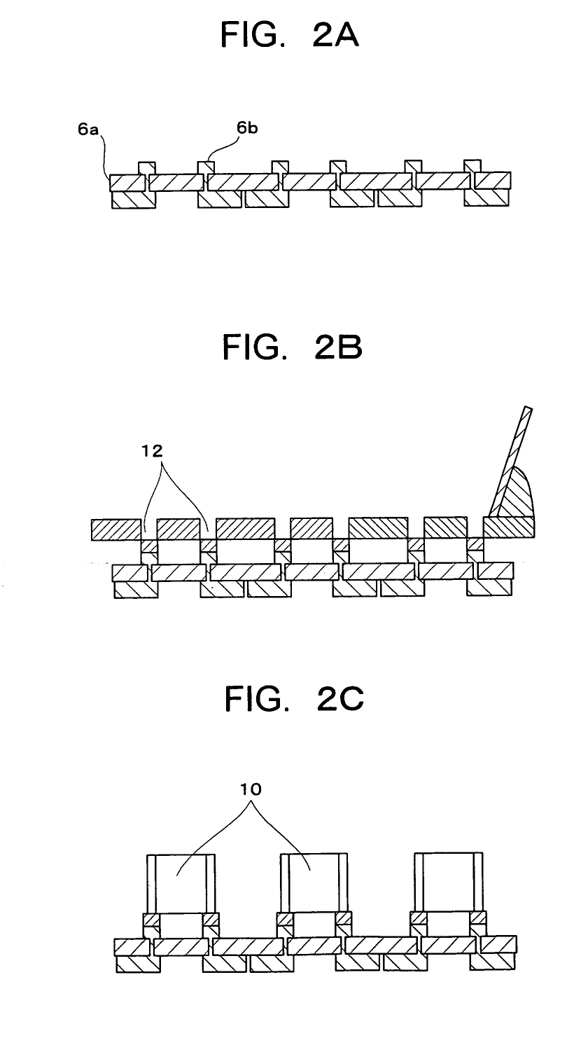

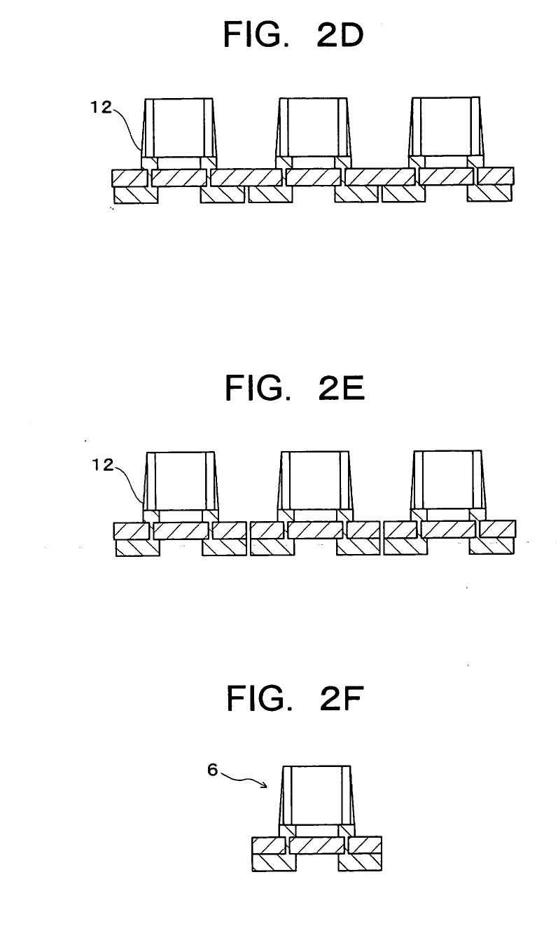

FIGS. 2A to 2F show an example of a manufacturing method of the above-described sub wiring board 6. The sub wiring board 6 is constituted of an extremely thin wiring board or flexible wiring board whose thickness is about scores of microns. As shown in FIG. 2A, a plurality of conductor patterns 6b constituting the plural sub wiring boards 6 are formed on a wiring board material 6a formed in a plate shape or a tape shape.

Then, as shown in FIG. 2B, cream solder 12 is first deposited on the respective conductor patterns 6b by cream solder printing.

As shown in FIG. 2C, the electronic components 10 are mounted so that these are positioned on the cream solder 12.

As shown in FIG. 2D, the cream solder 12 is thermally melted by a reflow furnace to connect the conductor patterns 6b and the electronic components 10.

As shown in FIG. 2E, the wiring board material 6a is cut to obtain the separate sub wiring boards 6 as shown in FIG. 2F. The manufacturing method like this allows the plural sub wiring boards 6 to be manufactured efficiently.

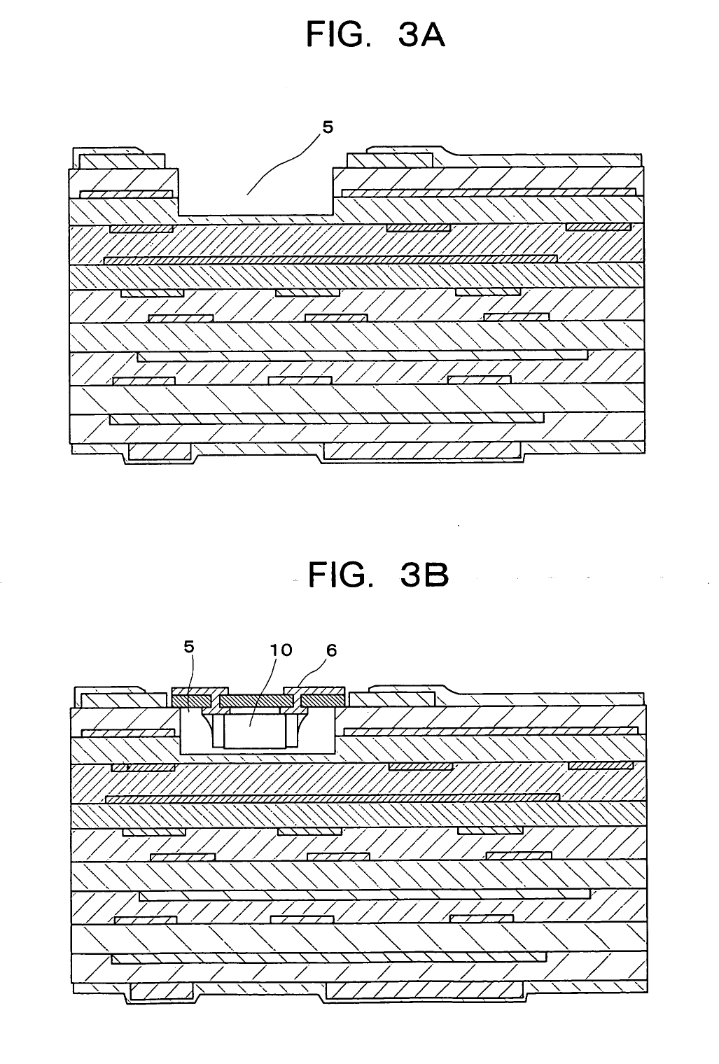

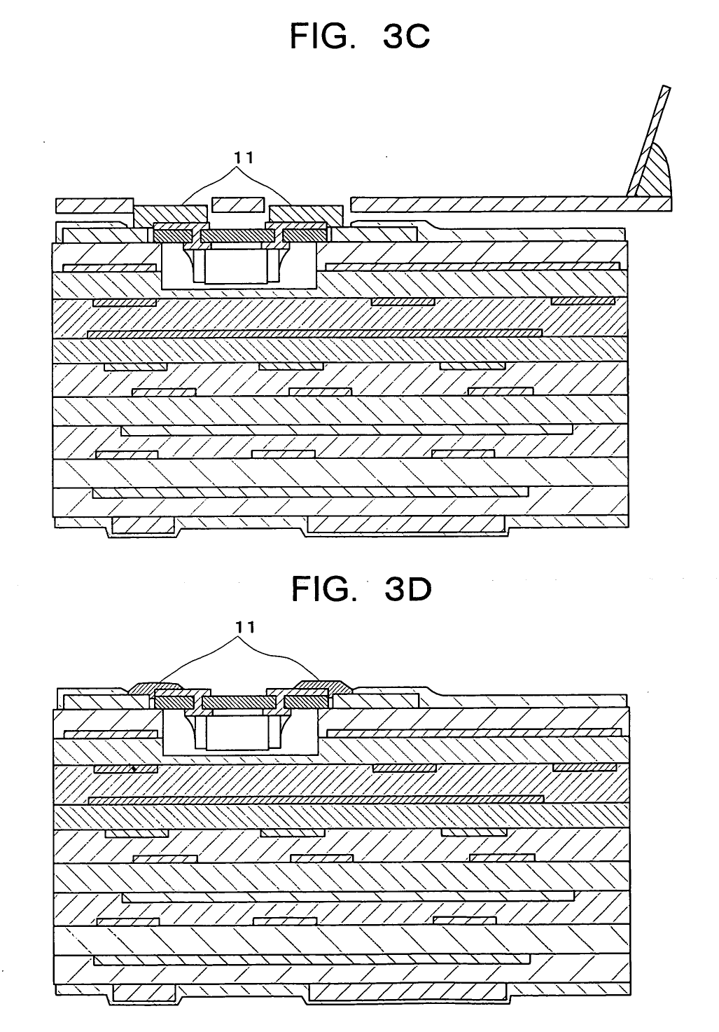

FIGS. 3A to 3D show an example of the connecting process of the main wiring board and the sub wiring board. As shown in FIG. 3A, the recessed portion 5 having the predetermined shape is formed in the main wiring board in advance. This recessed portion 5 may be formed by, for example, cutting process using a laser and the like. Then, as shown in FIG. 3B, the sub wiring board 6 is first mounted so that the electronic component 10 is positioned inside the recessed portion 5.

As shown in FIG. 3C, the cream solder 11 is deposited on the conductor pattern which is the part connecting the sub wiring board 6 and the main wiring board. Thereafter, as shown in FIG. 3D, the cream solder 11 is thermally melted by the reflow furnace to connect the sub wiring board 6 and the main wiring board. The manufacturing method like this allows the sub wiring board 6 to be connected to the main wiring board efficiently, and the wiring board to be manufactured efficiently.

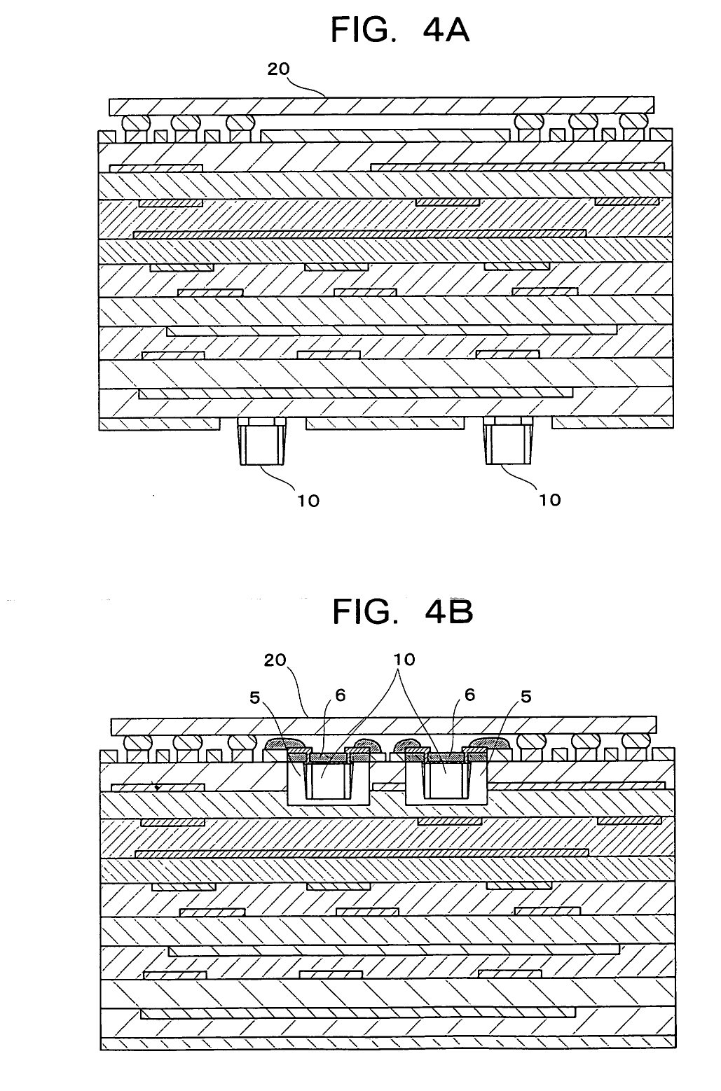

According to this embodiment, the electronic component 10 of the sub wiring board 6 is housed inside the recessed portion 5 of the main wiring board as described above, and the electronic component 10 is not projected from the main wiring board. Accordingly, as shown in FIG. 4B, a large electronic component 20 such as an LSI (BGA (ball grid array) and the like) can be arranged over the sub wiring board 6 so as to cover the sub wiring board 6.

FIG. 4A shows the configuration of a conventional wiring board on which similar electronic components 10 and 20 are mounted for comparison. As shown in FIG. 4A, when the electronic components 10 (for example, bypass capacitor and decoupling) and the electronic component 20 (for example, LSI and the like) are mounted in the conventional art, these need to be arranged on both surfaces of the wiring board dispersively, thereby causing the problems such as the occurrence of parasitic conductance and the difficulty in attaining densification because the capacitor and the like are arranged on the rear surface side and other electronic components cannot be mounted thereon.

According to this embodiment, the electronic component 10 such as the bypass capacitor and the electronic component 20 such as the LSI can be arranged close to each other on the same surface side. Since the parasitic conductance can be reduced and electric noises can be reduced, its performance as an electric circuit can be improved as well. Further, since the total thickness can be reduced as compared to the conventional art, it is possible to attain miniaturization. Moreover, since other electronic components can be mounted on the rear surface side, it is also possible to attain densification.

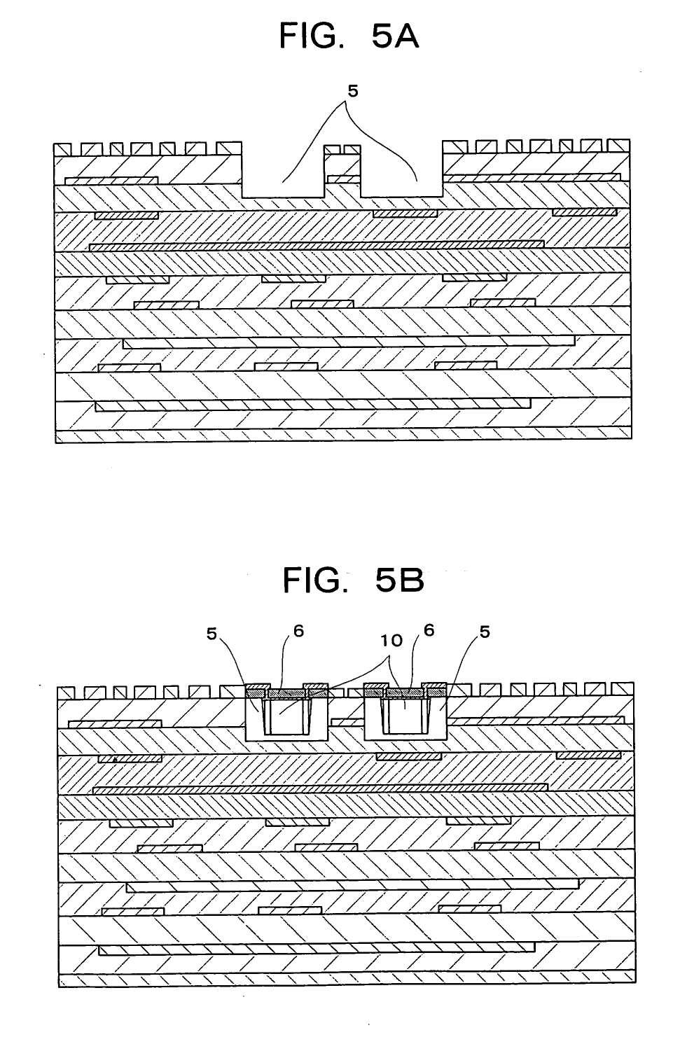

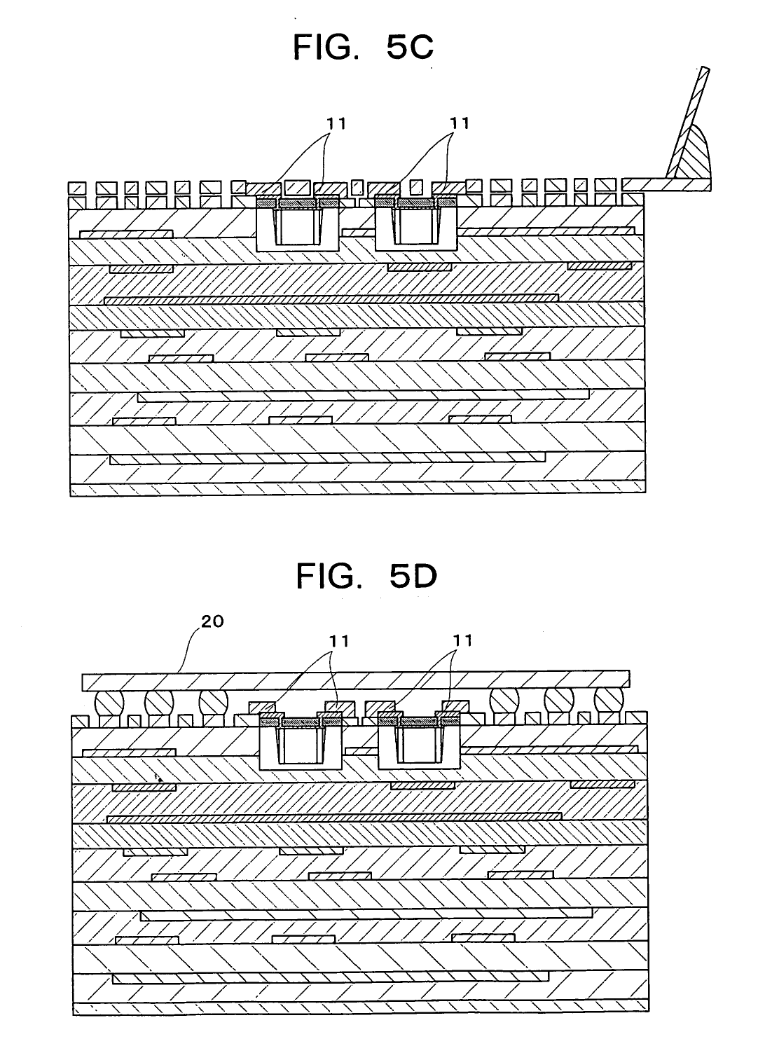

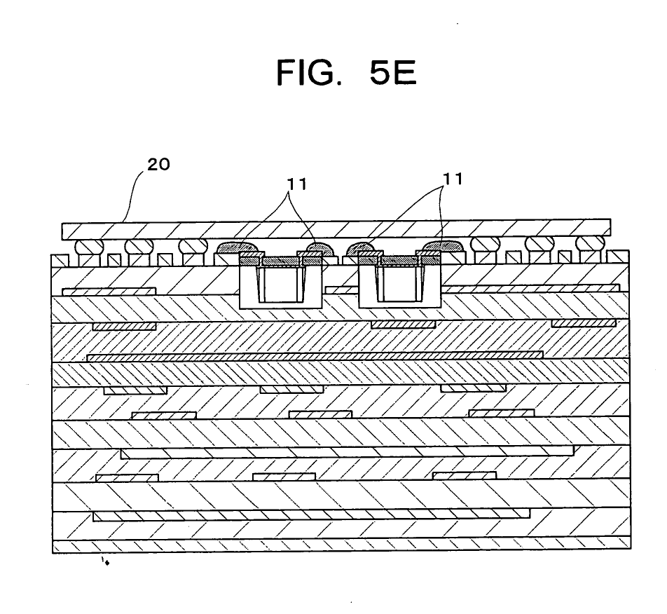

FIGS. 5A to 5E show an example of a manufacturing method of the wiring board configured as above. AS shown in FIG. 5A, a predetermined number (two in FIGS. 5A to 5E) of the recessed portions 5 having the predetermined shape are formed in the main wiring board in advance. These recessed portions 5 may be formed by, for example, the cutting process using the laser and the like. Then, as shown in FIG. 5B, the sub wiring boards 6 are mounted so that the electronic components 10 are positioned inside the recessed portions 5.

As shown in FIG. 5C, the cream solder 11 is deposited by the cream solder printing on the conductor patterns which are the parts connecting the sub wiring boards 6 and the main wiring board, and the part where the electronic component 20 is mounted as necessary when the electronic component 20 does not have solder balls and the like.

As shown in FIG. 5D, the electronic component 20 is mounted, and as shown in FIG. 5E, the cream solder 11 is thermally melted by the reflow furnace to connect the sub wiring boards 6 and the main wiring board, and the electronic component 20 and the main wiring board. The manufacturing method like this allows the soldering of the sub wiring boards 6 and the soldering of the electronic component 20 to be performed by the single process, and the wiring board to be manufactured efficiently in a short period of time.

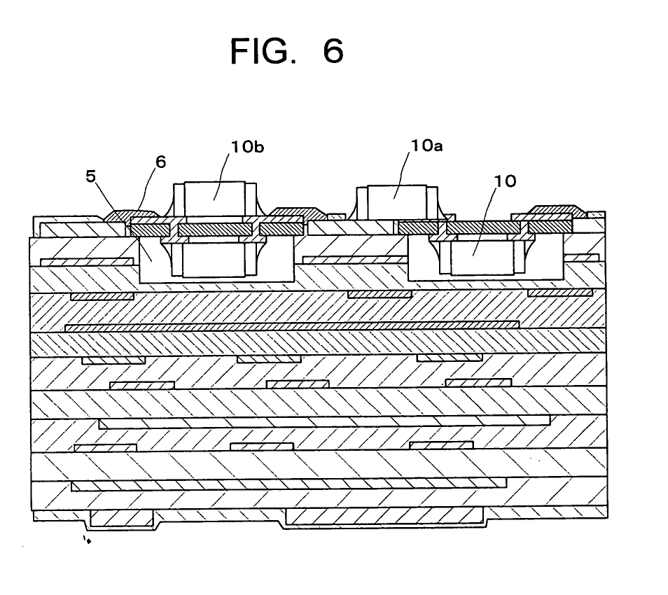

FIG. 6 shows the configuration of another embodiment. According to this embodiment, an electronic component 10a is arranged to extend across a sub wiring board 6 and a main wiring board on the upper side of the sub wiring board 6. Further, an electronic component 10b is arranged on the upper side of the sub wiring board 6. A greater number of electronic components than the conventional art can be mounted when the electronic components are small like these, which makes it possible to attain densification.

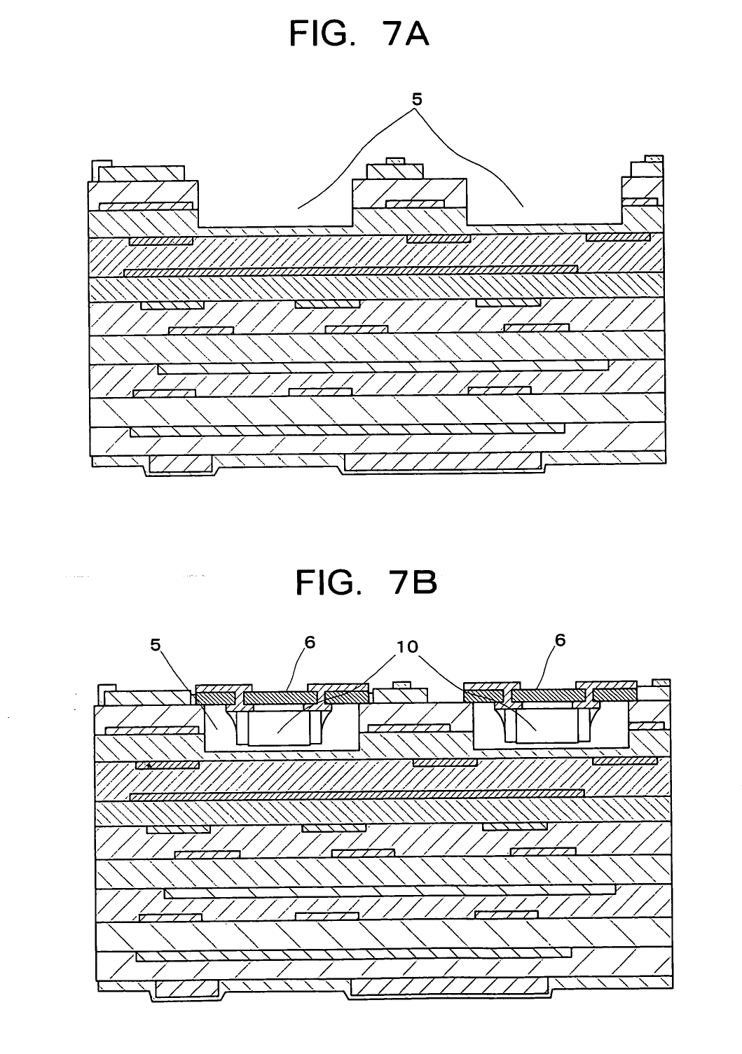

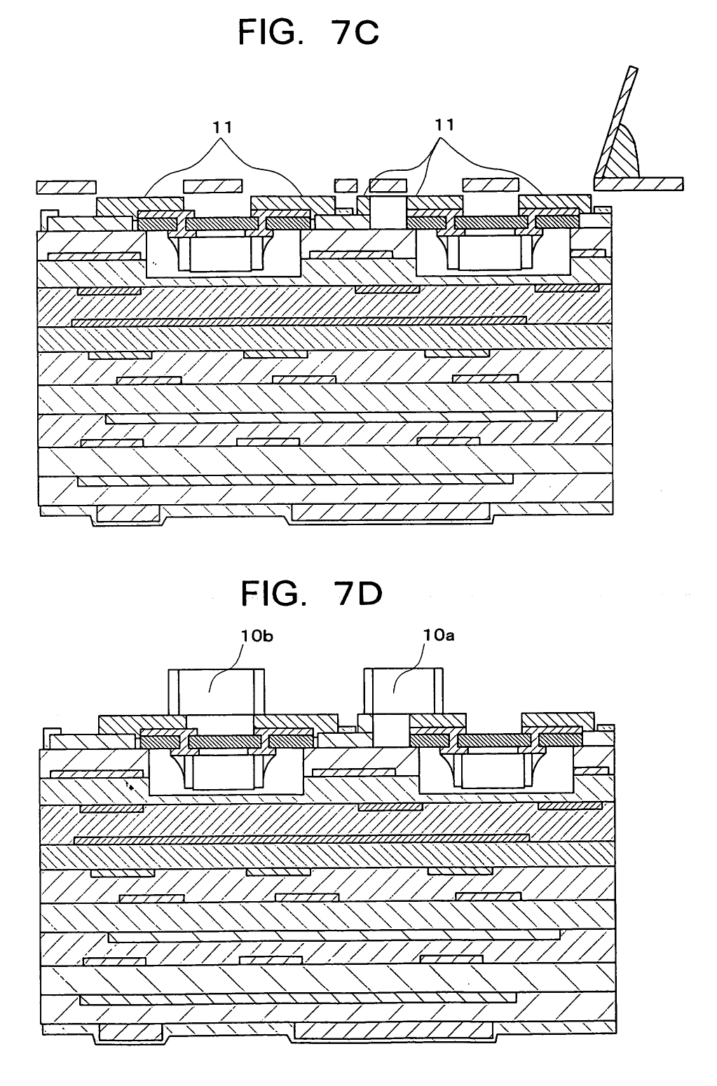

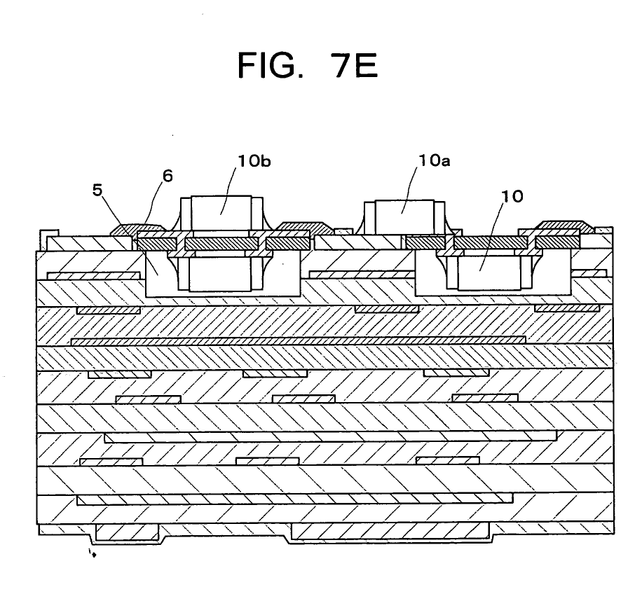

FIGS. 7A to 7E show an example of a manufacturing method of the wiring board configured as above. As shown in FIG. 7A, a predetermined number (two in FIGS. 7A to 7E) of recessed portions 5 having a predetermined shape are formed in the main wiring board in advance. These recessed portions 5 may be formed by, for example, cutting process using a laser and the like. Then, as shown in FIG. 7B, the sub wiring boards 6 are mounted so that electronic components 10 are positioned inside the recessed portions 5.

As shown in FIG. 7C, cream solder 11 is deposited by cream solder printing on conductor patterns which are the parts connecting the sub wiring boards 6 and the main wiring board, and the part where the other electronic components 10a and 10b are mounted.

As shown in FIG. 7D, the electronic components 10a and 10b are mounted, and as shown in FIG. 7E, the cream solder 11 is thermally melted by a reflow furnace to connect the sub wiring boards 6 and the main wiring board, and the electronic components 10a and 10b and the main wiring board and the sub wiring boards 6. The manufacturing method like this allows the soldering of the sub wiring boards 6 and the soldering of the electronic components 10a and 10b to be performed by the single process, and the wiring board to be manufactured efficiently in a short period of time.

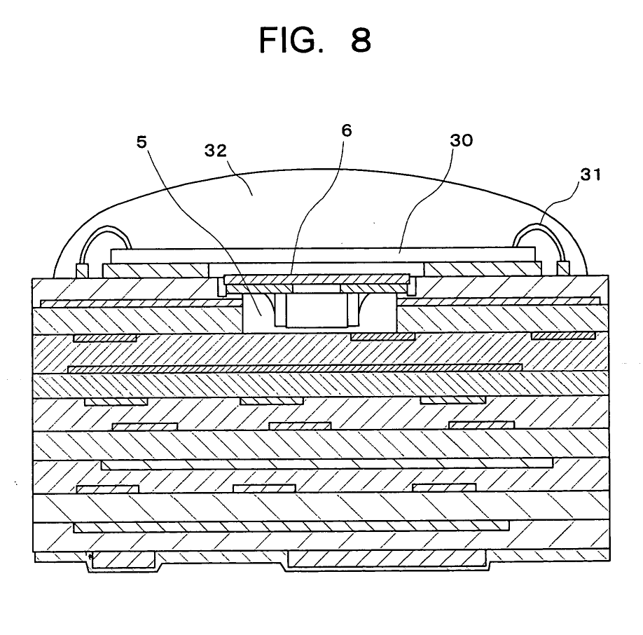

FIG. 8 shows the configuration of another embodiment. According to this embodiment, a large electronic component 30 is arranged over a sub wiring board 6, and the electronic component 30 and a main wiring board are connected by wire bonding 31 and sealed by resin 32. The electronic component to be arranged over the sub wiring board 6 to cover the sub wiring board 6 is not limited to BGA and the like, and it may be an electronic component to be electrically connected by the wire bonding 31 and the like.

What is claimed is:

1. A wiring board, comprising:
a main wiring board constituted of a multilayer wiring board, and having a recessed portion in a predetermined shape formed therein;
a sub wiring board having a first electronic component mounted thereon, and fixed to said main wiring board so that the first electronic component is positioned inside the recessed portion; and
a second electronic component whose size is larger than said sub wiring board, arranged to cover an upper part of said sub wiring board, and fixed to said main wiring board.

2. A wiring board according to claim 1,
wherein said second electronic component comprises an LSI.

3. A wiring board according to claim 1,
wherein a plurality of the recessed portions are formed, and said subwiring boards are respectively fixed at the recessed portions of said main wiring board.

4. A wiring board according to claim 3,
wherein said second electronic component is arranged to cover upper parts of said plural sub wiring boards.

5. A wiring board according to claim 4,
wherein said second electronic component comprises an LSI.

6. A wiring board, comprising:
a main wiring board constituted of a multilayer wiring board, and having a recessed portion in a predetermined shape formed therein;
a sub wiring board having a first electronic component mounted thereon, and fixed to said main wiring board so that the first electronic component is positioned inside the recessed portion; and
a second electronic component fixed to extend across said sub wiring board and said main wiring board.

7. A wiring board according to claim 6,
wherein a plurality of the recessed portions are formed, and said subwiring boards are respectively fixed at the recessed portions of said main wiring board.

8. A method of manufacturing a wiring board, comprising:
manufacturing a subwiring board, comprising depositing cream solder on predetermined positions on a wiring board material on which a plurality of predetermined conductor patterns are formed, mounting a plurality of first electronic components on the predetermined positions on the wiring board material, thermally melting the cream solder to connect the first electronic components and the wiring board material, and cutting the wiring board material into separate sub wiring boards; and
connecting the sub wiring board and a main wiring board, comprising forming a recessed portion in a predetermined shape in the main wiring board constituted of a multilayer wiring board, mounting the sub wiring board on the main wiring board so that the first electronic component is positioned inside the recessed portion, depositing the cream solder on a predetermined position, and thermally melting the cream solder to connect the sub wiring board and the main wiring board.

9. A method of manufacturing the wiring board according to claim 8,
wherein a plurality of the recessed portions are formed, and the sub wiring boards are respectively mounted at the recessed portions of the main wiring board.

10. A method of manufacturing the wiring board according to claim 8,
wherein said connecting of the sub wiring board and the main wiring board further comprises mounting a second electronic component whose size is larger than the sub wiring board, to cover an upper part of the sub wiring board, after the depositing of the cream solder, and
wherein, in the thermally melting, the cream solder is melted to connect the sub wiring board and the main wiring board, and connect the second electronic component and the main wiring board.

11. A method of manufacturing the wiring board according to claim 10,
wherein a plurality of the recessed portions are formed, and the sub wiring boards are respectively mounted at the recessed portions of the main wiring board.

12. A method of manufacturing the wiring board according to claim 11,
wherein the second electronic component is arranged to cover upper parts of the plural sub wiring boards.

13. A method of manufacturing the wiring board according to claim 8,
wherein said connecting of the sub wiring board and the main wiring board further comprises mounting a second electronic component to extend across the sub wiring board and the main wiring board after the depositing of the cream solder, and
wherein, in the thermally melting, the cream solder is melted to connect the sub wiring board and the main wiring board, and connect the second electronic component and the main wiring board, and the second electronic component and the sub wiring board.

14. A method of manufacturing the wiring board according to claim 13,
wherein a plurality of the recessed portions are formed, and the sub wiring boards are respectively mounted at the recessed portions of the main wiring board.
